(19) United States
(12) Patent Application Publication
(10) Pub. No.: US 2025/0311177 A1
(43) Pub. Date: Oct. 2, 2025

(54) ELECTRONIC DEVICE

(71) Applicant: Dr. Ing. h.c. F. Porsche Aktiengesellschaft, Stuttgart (DE)

(72) Inventors: Patrick KNECHT, Stuttgart (DE); Markus OMLOR, Wuerzburg (DE); Sebastian WACHTER, Pressig (DE); Maximilian BARKOW, Stuttgart (DE)

(21) Appl. No.: 18/617,905

(22) Filed: Mar. 27, 2024

(51) Int. Cl. H05K 7/20; H02M 7/00

(52) U.S. Cl. CPC H05K 7/20927; H02M 7/003

(57) ABSTRACT

An electronic device, in particular a pulse inverter for a motor vehicle, including a housing with a housing interior. The housing has at least one partition wall, which divides the housing interior in a sealed manner into a first interior region and a second interior region a media-tight interface being provided in a recess in the partition wall, which interface is formed in one piece with the partition wall from a plastic material.

### CROSS REFERENCE TO RELATED APPLICATIONS

This application claims benefit to German Patent Application No. DE 10 2023 108 618.9, filed on Apr. 4, 2023, which is hereby incorporated by reference herein.

### FIELD

The invention relates to an electronic device, in particular a pulse inverter, especially for a motor vehicle.

### BACKGROUND

Pulse inverters are known in motor vehicles, which have a housing in which electronic components are arranged. These electronic components are typically arranged together in the interior of the housing so that no spatial separation is present or required. If components in the interior are fluid-cooled, for example, fluid lines are routed through the housing wall of the housing and led to the fluid-cooled component and connected in a sealed manner so that the fluid for cooling the component can flow into the component, flow through the component and then flow out of the component again. The sealing connection of the fluid lines allows the fluid to be safely routed into the housing to the component and out of the component and out of the housing again. However, this design has the disadvantage that the fluid for cooling the component does not always reach it well, so that optimum cooling of the component to be cooled is not always achieved. Another disadvantage of routing the fluid lines through the housing is that there is a certain risk of the fluid lines in the housing leaking and the fluid that then escapes affecting or damaging other components in the housing.

It is also known that components can be operated with direct fluid cooling so that the cooling fluid can freely flow directly against and around the component. However, this has the disadvantage that this fluid flow is not suitable and permissible for all components in the housing without impairing the performance of sensitive components or even damaging them.

### SUMMARY

In an embodiment, the present disclosure provides an electronic device, in particular a pulse inverter for a motor vehicle, comprising a housing with a housing interior. The housing has at least one partition wall, which divides the housing interior in a sealed manner into a first interior region and a second interior region a media-tight interface being provided in a recess in the partition wall, which interface is formed in one piece with the partition wall from a plastic material.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a schematic sectional view of an electronic device according to an embodiment example of the invention.

### DETAILED DESCRIPTION

In an embodiment, the present invention provides an electronic device which is improved with regard to the cooling of components to be cooled and yet is designed in such a way that other components are not adversely affected and at the same time the electrical contacting of components in the housing is safely ensured.

An embodiment example of the invention relates to an electronic device, in particular a pulse inverter, in particular for a motor vehicle, having a housing with a housing interior, wherein the housing has at least one partition wall which divides the housing interior into a first interior region and a second interior region in a sealed manner, wherein a media-tight interface is provided in a recess in the partition wall, which interface is formed from a plastic material integrally connected to the partition wall. This makes it possible to create an electronic device that allows reliable sealing, does not require many fault-prone interfaces and can be produced at low cost.

It is particularly advantageous if the media-tight interface is produced by transfer molding the plastic material. This allows the interface to be produced in a permanently secure and sealing design that is also cost-effective to manufacture.

In an embodiment example, it is also expedient if at least one component or a plurality of components is integrated into the media-tight interface, which causes or causes an electrical contact from the first interior region to the second interior region. This means that at least one electrical connection can be permanently created and used thanks to the media-tight interface despite its sealed design. This allows electrical and/or electronic components that require different treatment to be arranged in different regions of the interior, which can still be electrically connected to each other via the media-tight interface.

It is also useful if the integration of the at least one component or the plurality of components into the media-tight interface has taken place during transfer molding. The media-tight interface is thus created in an integrated process by transfer molding, a primary molding process using plastic material under temperature and pressure, and at the same time at least one component or the components are integrated into the plastic material.

It is also useful if the component is an electrical component or an electronic component, for example an electrical contact strip, several electrical contact strips, an electronic semiconductor component, an electronic power semiconductor component, etc. This means that components can be integrated that only generate an electrical contact and/or components can be integrated that are also an electronic component or comprise an electronic component.

It is also expedient if at least one first electrical and/or electronic component and at least one second electrical and/or electronic component are provided, wherein the at least one first electrical and/or electronic component is arranged in the first interior region and the at least one second electrical and/or electronic component is arranged in the second interior region. This means that different electronic and/or electrical components can also be arranged in the respective interior regions, which can also be treated differently, for example cooled differently. In this way, components can be used that are directly exposed to or surrounded by coolant in order to cool them, and components that would not withstand such direct cooling can be arranged in a different interior region.

It is also expedient if the housing has a first fluid inlet connection in the region of the first interior region for feeding a first fluid into the first interior region and a first fluid outlet connection for discharging the first fluid from the first interior region, wherein the first fluid flows through the first interior region. For example, air can flow directly through an interior region, in particular for direct cooling of components arranged in it. This is particularly useful for components that generate a lot of heat during operation.

Thus, it is also expedient if the first fluid flows against or around the at least one first electrical and/or electronic component in the first interior region. These directly cooled components can thus be cooled particularly effectively.

It is also advantageous if the housing has a second fluid inlet connection in the region of the second interior region for feeding a second fluid into the second interior region and a second fluid outlet connection for discharging the second fluid from the second interior region, wherein the second fluid flows through the second interior region. This means that components can also be cooled differently, for example with air as the second fluid, while a liquid coolant is used as the first fluid, in particular a dielectric first fluid. Different requirements can thus be met.

This allows different requirements to be taken into account. For example, the second fluid is air. For example, a liquid coolant can also be used as the first fluid, in particular a dielectric first fluid.

Embodiments of the invention are described in detail in the following on the basis of an embodiment example with reference to the drawing.

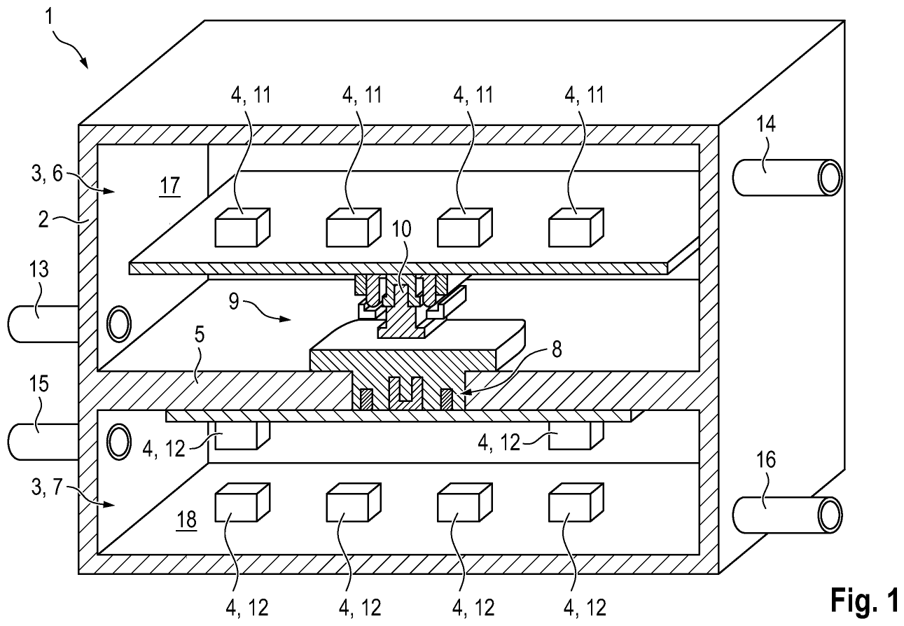

FIG. 1 shows a schematic sectional view of an embodiment example of an electronic device 1, which can be designed as a pulse inverter, for example, as a pulse inverter for a motor vehicle.

The electronic device 1 has a housing 2 with a housing interior 3 in which electrical and/or electronic components are arranged.

The housing 2 has at least one partition wall 5, which divides the housing interior 3 into a first interior region 6 and a second interior region 7 in a sealed manner.

Since electrical and/or electronic components 4 are arranged in the two interior regions 6, 7, some of which are electrically conductively connected or interconnected, at least one electrical connection must be provided which extends through the partition wall 5 in a sealed manner.

For this purpose, a media-tight interface 9 is provided in a recess 8 of the partition wall 5, which is made of a plastic material connected in one piece with the partition wall 5. The media-tight interface 9 is preferably produced by transfer molding the plastic material.

To effect the electrically conductive connection through the media-tight interface 9, at least one component 10 or a plurality of components 10 is integrated into the media-tight interface 9, which causes or causes an electrical contact from the first interior region 6 to the second interior region 7. The at least one component 10 is integrated in one piece into the plastic material during the production of the media-tight interface 9.

The integration of the at least one component 10 or the plurality of components 10 into the media-tight interface 9 can therefore take place during transfer molding. This ensures that the electrical connection through the interface 9 can be made in an integrated process without additional design effort, so that additional sealing regions, seals and fastenings can be avoided.

Depending on the design of the media-tight interface 9, the component 10 can be an electrical component or an electronic component, for example an electrical contact strip, several electrical contact strips, an electronic semiconductor component, an electronic power semiconductor component, etc.

Since not only one media-tight interface 9 can be provided in a device 1 according to an embodiment of the invention, but also, for example, several and, if necessary, different media-tight interfaces 9 can be provided, the respective media-tight interface 9 can be formed, for example, with at least one of the above-mentioned components 10, wherein the same or different components 10 can be used as required.

The device 1 is preferably designed such that one or more components 4 can be provided, wherein at least one first electrical and/or electronic component 11 and at least one second electrical and/or electronic component 12 are provided, wherein the at least one first electrical and/or electronic component 11 is arranged in the first interior region 6 and the at least one second electrical and/or electronic component 12 is arranged in the second interior region 7.

In an embodiment example, it is also expedient if the housing 2 in the region of the first interior region 6 has a first fluid inlet connection 13 for feeding a first fluid 17 into the first interior region 6 and a first fluid outlet connection 14 for discharging the first fluid 17 from the first interior region 6, wherein the first fluid 17 flows through the first interior region 6 from the fluid inlet connection 13 to the fluid outlet connection 14. The first fluid 17 can flow against or around the at least one first electrical and/or electronic component 4, 11 in the first interior region 6. The first fluid 17 can be a coolant, for example a fluid. It can be a cooling oil, a dielectric fluid, etc.

It is also optionally provided, for example, that alternatively or additionally the housing 2 in the region of the second interior region 7 has a second fluid inlet connection 15 for feeding a second fluid 18 into the second interior region 7 and a second fluid outlet connection 16 for discharging the second fluid 18 from the second interior region 7, wherein the second fluid 18 flows through the second interior region 7 from the fluid inlet connection 15 to the fluid outlet connection 16. The second fluid 18 can flow against or around the at least one second electrical and/or electronic component 4, 12 in the second interior region 7. The second fluid 18 can be a coolant, for example a fluid or a gas, air, nitrogen, etc. It can be a cooling oil, a dielectric fluid, etc.

Preferably, the second fluid 18 is different from the first fluid 17.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An electronic device, in particular a pulse inverter for a motor vehicle, comprising:
a housing with a housing interior, wherein the housing has at least one partition wall, which divides the housing interior in a sealed manner into a first interior region and a second interior region a media-tight interface being provided in a recess in the partition wall, which interface is formed in one piece with the partition wall from a plastic material.

2. The electronic device according to claim 1, wherein the media-tight interface is produced by transfer molding of the plastic material.

3. The electronic device according to claim 1, wherein at least one component is integrated into the media-tight interface, the at least one component effecting an electrical contact from the first interior region to the second interior region.

4. The electronic device according to claim 3, wherein the integration of the at least one component into the media-tight interface takes place during transfer molding.

5. The electronic device according to claim 1, wherein the at least one component includes an electrical component, an electrical contact strip, an electronic semiconductor component, or an electronic power semiconductor component.

6. The electronic device according to claim 1, further comprising at least one first electrical and/or electronic component and at least one second electrical and/or electronic component,
wherein the at least one first electrical and/or electronic component is arranged in the first interior region and the at least one second electrical and/or electronic component is arranged in the second interior region.

7. The electronic device according to claim 6, wherein the housing has, in a region of the first interior region, a first fluid inlet connection for feeding a first fluid into the first interior region and a first fluid outlet connection for discharging the first fluid from the first interior region, wherein the first fluid flows through the first interior region.

8. The electronic device according to claim 7, wherein the at least one first electrical and/or electronic component in the first interior region is flowed against or around by the first fluid.

9. The electronic device according to claim 7, wherein the housing has, in a region of the second interior region, a second fluid inlet connection for feeding a second fluid into the second interior region and a second fluid outlet connection for discharging the second fluid from the second interior region, wherein the second fluid flows through the second interior region.

10. The electronic device according to claim 9, wherein the second fluid is different from the first fluid.
